(19) United States
(12) Patent Application Publication
(10) Pub. No.: US 2025/0357426 A1
(43) Pub. Date: Nov. 20, 2025

(54) PROCESSORS AND MEMORY DEVICES WITH PROCESSING CIRCUITS

(71) Applicant: Samsung Electronics Co., Ltd., Suwon-si (KR)

(72) Inventors: Rekha PITCHUMANI, Oak Hill, VA (US); Hyoun Kwon JEONG, Pleasanton, CA (US); Yangwook KANG, San Jose, CA (US); Yang Seok KI, Palo Alto, CA (US); Soogil JEONG, Pleasanton, CA (US); Myung June JUNG, Santa Clara, CA (US)

(21) Appl. No.: 19/211,106

(22) Filed: May 16, 2025

Related U.S. Application Data
(60) Provisional application No. 63/649,012, filed on May 17, 2024.
(60) Provisional application No. 63/666,105, filed on Jun. 28, 2024.
(60) Provisional application No. 63/766,479, filed on Mar. 4, 2025.
(60) Provisional application No. 63/766,467, filed on Mar. 4, 2025.

(51) Int. Cl. H01L 25/065; G06F 13/16; G06F 13/40

(52) U.S. Cl. CPC H01L 25/0655; G06F 13/1668; G06F 13/4068

(57) ABSTRACT

Processors and memory devices with processing circuits are disclosed. An apparatus may include a first memory device, a second memory device, and a compute device. The first memory device may include a first base die and a first memory die attached to the first base die. The first base die may include a first die-to-die interface, a second die-to-die interface, and a first processing circuit. The second memory device may include a second base die and a second memory die attached to the second base die. The second base die may include a third die-to-die interface, a fourth die-to-die interface, and a second processing circuit. The compute device may be connected to the first die-to-die interface and the third die-to-die interface.

### RELATED APPLICATION DATA

This application claims the benefit of U.S. Provisional Patent Application Ser. No. 63/649,012, filed May 17, 2024, which is incorporated by reference herein for all purposes.

### FIELD

The disclosure relates generally to processors and memory devices, and more particularly to processors and memory devices with processing circuits.

### BACKGROUND

Compute resources and memory resources are utilized differently for different applications. Compute resources are generally provided by a processor (e.g., a central processing unit) while memory resources are typically provided by a memory (e.g., a random access memory). Performance of applications and operations within the applications may be limited based on compute resources, memory resources, or both.

### BRIEF DESCRIPTION OF THE DRAWINGS

The drawings described below are examples of how embodiments of the disclosure may be implemented, and are not intended to limit embodiments of the disclosure. Individual embodiments of the disclosure may include elements not shown in particular figures and/or may omit elements shown in particular figures. The drawings are intended to provide illustration and may not be to scale.

FIG. 1 illustrates a system including a memory device and a compute device, according to embodiments of the disclosure.

FIG. 2 illustrates a memory die of a memory device, according to embodiments of the disclosure.

FIG. 3 illustrates a base die of a memory device, according to embodiments of the disclosure.

FIG. 4 illustrates a processing circuit, according to embodiments of the disclosure.

FIG. 5 illustrates an example of a system-in-package, according to embodiments of the disclosure.

FIG. 6 illustrates an example of a system-in-package, according to embodiments of the disclosure.

FIG. 7 illustrates an example of a system-in-package, according to embodiments of the disclosure.

FIG. 8 illustrates a compute/memory tray, according to embodiments of the disclosure.

### SUMMARY

An apparatus may include a first memory device, a second memory device, and a compute device. The first memory device may include a first base die and a first memory die attached to the first base die. The first base die may include a first die-to-die interface, a second die-to-die interface, and a first processing circuit. The second memory device may include a second base die and a second memory die attached to the second base die. The second base die may include a third die-to-die interface, a fourth die-to-die interface, and a second processing circuit. The compute device may be connected to the first die-to-die interface and the third die-to-die interface.

An apparatus may include a first system-in-package, a second system-in-package, and a first processor connected to the first system-in-package and the second system-in-package. The first system-in-package may include a first memory device and a first compute device. The first memory device may include a first base die including a first processing circuit and a first die-to-die interface and a first memory die attached to the first base die. The first compute device may be connected to the first die-to-die interface. The second system-in-package may include a second memory device and a second compute device. The second memory device may include a second base die including a second processing circuit and a second die-to-die interface and a second memory die attached to the second base die. The second compute device may be connected to the second die-to-die interface.

A system may include a first tray and a second tray. The first tray may include a first system-in-package, a second system-in-package, and a first interface. The first system-in-package may include a first memory device and a first compute device connected to the first memory device. The first memory device may include a first base die including a first processing circuit and a first memory die attached to the first base die. The second system-in-package may include a second memory device and a second compute device connected to the second memory device. The second memory device may include a second base die including a second processing circuit and a second memory die attached to the second base die. The second tray may include a third system-in-package and a second interface. The third system-in-package may include a third memory device and a third compute device connected to the third memory device. The third memory device may include a third base die including a third processing circuit and a third memory die attached to the third base die. The second interface may be connected to the first interface.

### DETAILED DESCRIPTION

Reference will now be made in detail to embodiments of the disclosure, examples of which are illustrated in the accompanying drawings. In the following detailed description, numerous specific details are set forth to enable a thorough understanding of the disclosure. It should be understood, however, that persons having ordinary skill in the art may practice the disclosure without these specific details. In other instances, well-known methods, procedures, components, circuits, and networks have not been described in detail so as not to unnecessarily obscure aspects of the embodiments.

It will be understood that, although the terms first, second, etc. may be used herein to describe various elements, these elements should not be limited by these terms. These terms are only used to distinguish one element from another. For example, a first module could be termed a second module, and, similarly, a second module could be termed a first module, without departing from the scope of the disclosure.

The terminology used in the description of the disclosure herein is for the purpose of describing particular embodiments only and is not intended to be limiting of the disclosure. As used in the description of the disclosure and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The components and features of the drawings are not necessarily drawn to scale.

Compute resources and memory resources are utilized differently for different applications and operations within the applications. Depending on the applications, the operations, and/or hardware availability, performance of the operations may be limited based on compute resources, memory resources, or both. In order to overcome such limitations, a first processing circuit is included in a first base die of a first memory device.

The first memory device includes a first memory die attached to the first base dic. For instance, the first memory device may provide compute resources via the first processing circuit. The first memory device can provide memory resources via the first memory die. To increase compute and/or memory resources, the first memory device may be connected to a second memory device. For example, the first base die may include a first die-to-die interface that can be connected to a second die-to-die interface of a second base die included in the second memory device.

The second memory device can include a second memory die attached to the second base die. The second base die may include a second processing circuit. Similar to the first memory device, the second memory device may provide compute resources via the second processing circuit and the second memory device may provide memory resources via the second memory die. Notably, many such memory devices can be connected as described relative to the first and second memory devices.

For additional compute and/or memory resources, the first and second memory devices may be included together along with a first compute device in a first system-in-package (which can include many additional memory devices). For instance, the first compute device manages operations of the first and second memory devices and the first compute device also provides compute resources for the first system-in-package.

The first system-in-package may be connected to a second system-in-package. In some embodiments, the first and second system-in-packages are connected by one or more accelerator links. The second system-in-package can include a third memory device, a fourth memory device, and a second compute device. The second compute device may be configured to manage operations of the third and fourth memory devices. In some embodiments, the third and fourth memory devices are structured similarly to the first and second memory devices, respectively. In other embodiments, the third and/or fourth memory devices may be different from the first and/or second memory devices.

The first system-in-package and the second system-in-package can be included together in a first compute/memory tray. In some embodiments, the first compute/memory tray includes a first management processor, a first network interface, and a first tray-to-tray interface. For instance, the first and second system-in-packages may be connected to the first management processor and the first tray-to-tray interface. The first network interface may be connected to the first management processor and the first tray-to-tray interface.

The first compute/memory tray may be connected to a second compute/memory tray (e.g., via one or more tray-to-tray interfaces). In some embodiments, the second compute/memory tray includes third and fourth system-in-packages, a second management processor, a second network interface, and a second tray-to-tray interface. The second management processor may be connected to the third and fourth system-in-packages and the second network interface. In some embodiments, the second tray-to-tray interface is connected to the third and fourth system-in-packages and the second network interface. For instance, the second tray-to-tray interface may also be connected to the first tray-to-tray interface such that the third and fourth system-in-packages can be connected to the first and second system-in-packages.

By including memory devices and a compute device in a system-in-package and by including one or more system-in-packages in a compute/memory tray as described above and below, compute and/or memory resources may be available for use by different applications and operations within the applications.

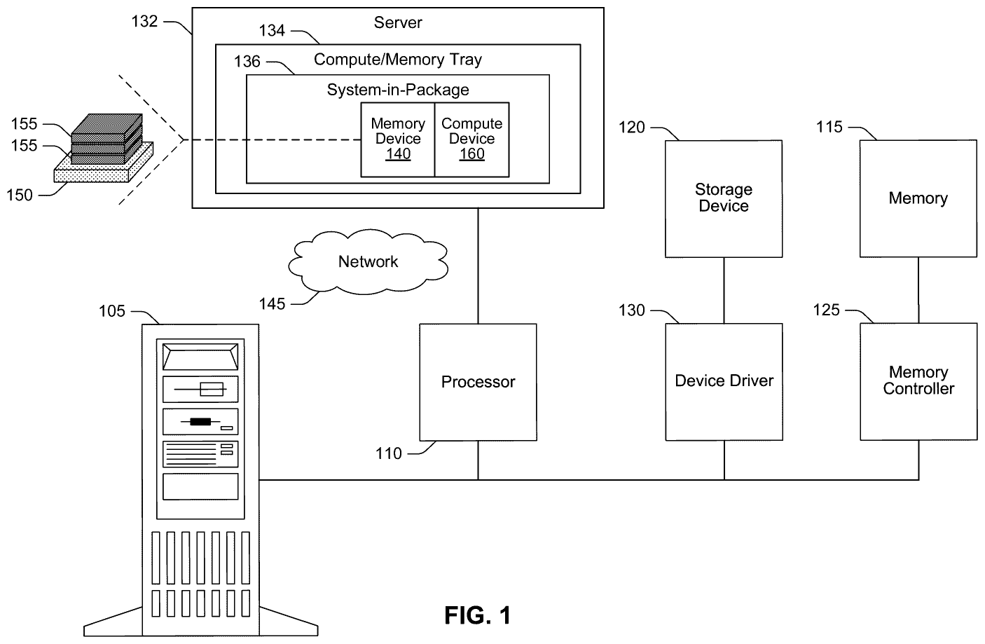

FIG. 1 illustrates a system including a memory device 140 and a compute device 160, according to embodiments of the disclosure. As shown in FIG. 1, a machine 105 (e.g., a host) includes a processor 110, a memory 115, and a storage device 120. The processor 110 is representative of a variety of types of processors such as central processing units (CPUs), accelerators, graphics processing units (GPUs), processors implemented using field-programmable gate arrays (FPGAs) (e.g., soft processors), etc. The memory 115 can include volatile memory and/or non-volatile memory and the memory 115 is representative of a variety of types of memory such as random access memory (RAM), static RAM (SRAM), dynamic RAM (DRAM), synchronous DRAM (SDRAM), etc.

Read/write operations performed relative to the memory 115 may be managed by a memory controller 125. In the illustrated example, the processor 110 is communicatively coupled to the memory controller 125 via a wired or wireless connection. The processor 110 is also shown to be communicatively coupled to the storage device 120 via a device driver 130. The device driver 130 can control the storage device 120 and the device driver 130 may be implemented using software, hardware, or a combination of software and hardware.

The system shown in FIG. 1 is illustrated to include a server 132 which includes one or more compute/memory trays 134 having compute and/or memory resources that may be communicatively coupled to the machine 105 via a wired or wireless connection. The compute/memory tray 134 may include one or more system-in-packages 136 which can include one or more memory devices 140 and one or more compute devices 160. As shown, a computed device 160 may be communicatively coupled to a memory device 140 within a system-in-package 136. In some embodiments, the memory device 140 is configured to provide compute and/or memory resources and the compute device 160 is configured to provide compute resources which can be communicatively coupled to the processor 110 via a wired or wireless connection. By way of example, the processor 110 may be coupled to the memory device 140 and the compute device 160 via a network 145.

In some embodiments, the memory device 140 and the compute device 160 are representative of one set/group of compute and/or memory resources included in the system-in-package 136. In other embodiments, the memory device 140 can be included in the storage device 120 or coupled to the storage device 120 via a wired or wireless connection such as the network 145. The compute device 160 may include one or more processors such CPUs, GPUs, accelerators, neural processing units (NPUs), tensor processing units (TPUs), etc. In some embodiments, the compute device 160 can include one or more memories, one or more caches, one or more integrated circuits, etc. Accordingly, the memory device 140 and the compute device 160 represent compute and/or memory capacity for use in a variety of different hardware environments that may be executing various types of applications. It is to be appreciated that, in some embodiments, the system-in-package 136 may include multiple memory devices 140 and/or multiple compute devices 160, the compute/memory tray 134 can include multiple system-in-packages 136, the server 132 may include multiple compute/memory trays 134, etc.

Compute and/or memory resources included in the memory device 140 may be physically disposed in a three-dimensional stack (e.g., to minimize distances between locations of the resources). In the example depicted in FIG. 1, the memory device 140 is illustrated to include a base die 150 and one or more memory die 155 attached to the base die 150 in a three-dimensional stack. In some embodiments, compute and/or memory resources of the memory device 140 are connected to the base die 150 and/or the memory die 155. For instance, including compute and/or memory resources of the memory device 140 in a three-dimensional stack of the memory die 155 attached to the base die 150 may minimize power consumed and physical space occupied by the compute and/or memory resources.

Although examples are described with respect to the memory die 155 attached to the base die 150, it is to be appreciated that, in some embodiments, compute and/or memory resources of the memory device 140 are included in other orientations (e.g., non-stacked orientations) and configurations (e.g., integrated configurations). It should also be appreciated that, in some embodiments, an additional base die 150 or another logic die can be included in the memory device 140. Accordingly, in some embodiments, the memory device 140 may include one or more additional base dies 150, one or more additional other logic dies, etc. Additionally, it should be appreciated that, in some embodiments, the memory die 155 can be stacked/disposed above and/or below the base die 150. Further, the memory die 155 may be stacked/disposed between a first base die 150 and a second base die 150.

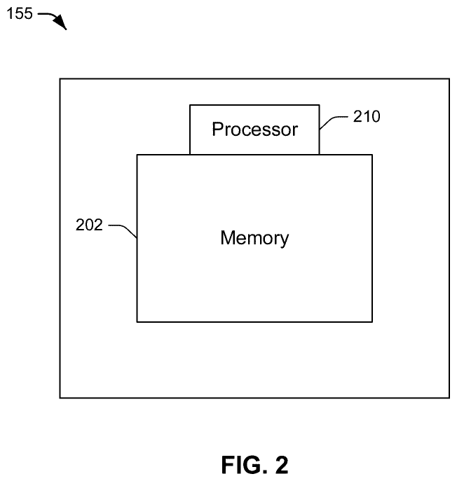

FIG. 2 illustrates a memory die 155 of a memory device 140, according to embodiments of the disclosure. As shown, the memory die 155 includes a memory 202. The memory 202 can include volatile memory and/or non-volatile memory and the memory 202 is representative of a variety of types of memory such as DRAM, SRAM, magnetoresistive RAM (MRAM), phase change memory (PCM), Flash, read-only memory (ROM), etc., and/or combinations of such. Accordingly, FIG. 2 depicts an example in which memory resources (e.g., the memory 202) of the memory device 140 are included in the memory die 155. In some embodiments, the memory die 155 includes one memory, two memories, more than two memories, etc. In some embodiments, the memory die 155 is a DRAM die, and the memory 202 represents DRAM.

In some optional embodiments, the memory die 155 includes a processor 210. Like the processor 110, the processor 210 is representative of a variety of types of processors such as CPUs, application specific integrated circuits (ASICs), accelerators, GPUs, etc. In the illustrated example, the processor 210 is coupled to the memory 202. Thus, FIG. 2 depicts an example in which memory resources (e.g., the memory 202) and compute resources (e.g., the processor 210) of the memory device 140 are included in the memory die 155. Although the example shown in FIG. 2 includes the processor 210, it is to be appreciated that, in some embodiments, the memory die 155 can include additional processors which may be structurally similar to the processor 210 or different from the processor 210.

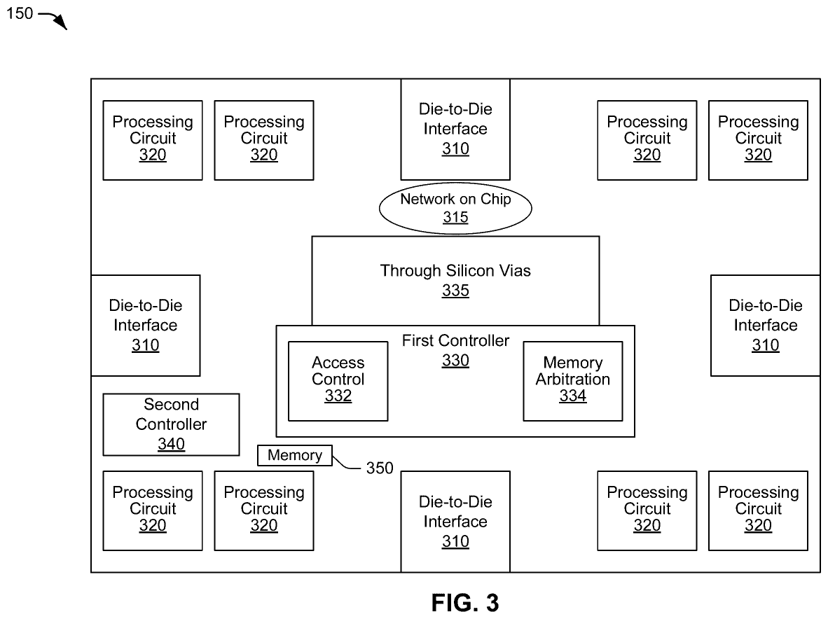

FIG. 3 illustrates a base die 150 of a memory device 140, according to embodiments of the disclosure. As shown, a base die 150 can include one or more die-to-die interfaces 310, a network on chip 315, one or more processing circuits 320, a first controller 330, through silicon vias 335, and an optional second controller 340. In an example in which the memory die 155 illustrated in FIG. 2 is a DRAM die, the first controller 330 may be a memory controller (e.g., a DRAM controller) configured to control the memory 202 using the through silicon vias 335.

As shown in FIG. 3, the first controller 330 can be connected to the through silicon vias 335. For instance, the through silicon vias 335 can communicatively couple (e.g., by multiple electrical connections) the memory 202 of the memory die 155 to the first controller 330 of the base die 150. In some embodiments, the first controller 330 may include access control 332 and memory arbitration 334 for managing access to the memory 202 as described below.

In a particular example, controller logic (CTL) of the first controller 330 can issue a command to a physical interface/layer (PHY) which converts the command into a signal for transmission to the memory die 155 by the through silicon vias 335. In the particular example, the through silicon vias 335 may transmit data read from the memory 202 of the memory die 155 to the PHY and the CTL. Although FIG. 3 is illustrated to include the through silicon vias 335, it is to be appreciated that, in some embodiments, hybrid bonding (e.g., dielectric-to-dielectric connections and conductor-to-conductor connections in a stacked configuration) may be used in addition or alternative to the through silicon vias 335. In some embodiments, universal chiplet interconnect express (UCIe) for horizontal/lateral and vertical connections (UCIe-3D) may be implemented as a protocol for horizontal/lateral and vertical communications between the base die 150 and the memory die 155.

In some embodiments, the die-to-die interfaces 310 are configured to interface with one or more additional dies and/or various types of compute and/or memory resources, as will be elaborated on below. The die-to-die interfaces 310 are representative of multiple different types of physical interfaces which can support different interface protocols/specifications such as UCIe, bunch of wires (BOW), advanced interface bus (AIB), opensource protocols/specifications (e.g., OpenHBI), etc. Although FIG. 3 illustrates four die-to-die interfaces 310, it is to be appreciated that, in some embodiments, the base die 150 includes less than four die-to-die interfaces 310 or more than four die-to-die interfaces 310.

As shown in FIG. 3, the base die 150 includes the network on chip 315 which may be internal to the base die 150 (e.g., integrated into the base die 150). The network on chip 315 may be configured to communicatively couple various devices/components (e.g., in a network-based architecture). For instance, the network on chip 315 may be configured to interface with an accelerator link, a memory controller, etc. In some embodiments, the network on chip 315 may connect the die-to-die interfaces 310 to the processing circuits 320, the first controller 330, the second controller 340, etc. In some embodiments, the network on chip 315 may communicatively couple the processing circuits 320 to each other and/or to the second controller 340.

The processing circuits 320 include compute and/or memory resources of the base die 150 of the memory device 140. In some embodiments, compute and/or memory resources are included in the processing circuits 320 in addition or alternative to compute and/or memory resources included in the memory die 155 of the memory device 140. In some embodiments, the optional second controller 340 is configured to control the processing circuits 320 by controlling or triggering kernel execution by the processing circuits 320. The second controller 340 can represent or include a management CPU configured to control operations of the processing circuits 320 such as setting parameters, collecting results, transmitting commands, etc. In some embodiments, the compute device 160 is configured to control the processing circuits 320 in addition or alternative to the second controller 340. For instance, the compute device 160 may control the processing circuits 320 by controlling or triggering kernel execution by the processing circuits 320.

In some embodiments, the processing circuits 320 are capable of accessing the memory 202 via the first controller 330 and the compute device 160 is also capable of accessing the memory 202 via the first controller 330. As noted above, the first controller 330 can include the access control 332 and the memory arbitration 334 for controlling access to the memory 202 by the processing circuits 320 and/or the compute device 160. In some embodiments, the first controller 330 may implement the access control 332 to partition or split the memory 202 into a first portion and a second portion that is separate from the first portion. In these embodiments, the processing circuits 320 can access the first portion of the memory 202 and the compute device 160 may access the second portion of the memory 202. In some embodiments, the first controller 330 may implement the memory arbitration 334 to resolve requests (e.g., conflicting requests) from the processing circuits 320 and the compute device 160 to access the memory 202. For instance, the first controller 330 may implement the memory arbitration 334 by executing logic included in the memory arbitration 334. In examples in which the compute device 160 controls the processing circuits 320, the compute device 160 may include the memory arbitration 334 in addition or alternative to the first controller 330 including the memory arbitration 334.

Although the first controller 330 and the second controller 340 are illustrated as two controllers, it is to be appreciated that, in some embodiments, the first controller 330 and the second controller 340 are implemented as a single controller. It also should be appreciated that by including the processing circuits 320 as part of the base die 150 in relatively close proximity to data (e.g., near the memory 202 of the memory die 155), the processing circuits 320 have faster access to the data at lower energy costs compared to an example in which the processing circuits 320 are not in relatively close proximity to the data. While eight processing circuits 320 are shown, it should be appreciated that, in some embodiments, the base die 150 includes more than eight processing circuits 320 or less than eight processing circuits 320. Additionally, it should be appreciated that the processing circuits 320 can be structured similarly such that a first one of the processing circuits 320 has first hardware and/or software and a second one of the processing circuits 320 has the first hardware and/or software. It is also to be appreciated that the processing circuits 320 may be different such that the first one of the processing circuits 320 has the first hardware and/or software and the second one of the processing circuits 320 has second hardware and/or software. In other words, the processing circuits 320 may be either homogeneous or non-homogenous.

In some embodiments, the base die 150 includes a memory 350 that can include volatile memory and/or non-volatile memory. For instance, the processing circuits 320 may utilize the memory 350 as a buffer memory for data copy operations. In some embodiments, the memory 350 can be utilized for preloading kernel binaries (e.g., to minimize or reduce kernel launch latency). It should be appreciated that, in some embodiments, the memory 350 may include SRAM. In some embodiments, the base die 150 can include one or more integrated circuits that may be configured to communicate with one or more additional base dies 150 included in a mesh network formed via the die-to-die interfaces 310, as will be discussed below. Accordingly, in various applications, the base die 150 may include one or more modifications which may include additional functional devices/components such as the memory 350.

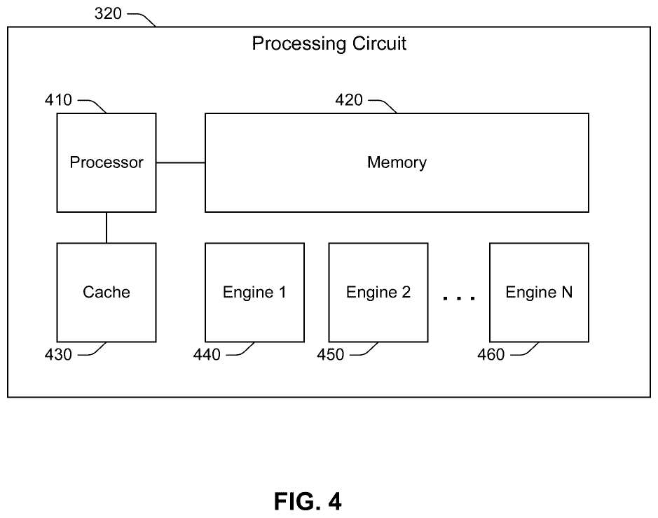

FIG. 4 illustrates a processing circuit 320, according to embodiments of the disclosure. As shown in FIG. 4, a processing circuit 320 includes a processor 410 and a memory 420. In some embodiments, the processing circuit 320 may include a cache 430 as well as engines 440, 450, 460. The processor 410 is representative of a variety of types of processors such as CPUs, accelerators, GPUs, NPUs, TPUs, etc. In some embodiments, the processor 410 includes multiple processors which may be different types of processors (e.g., a GPU, an NPU, and/or a TPU).

In general, the processor 410 is configured to execute instructions which may be included in the memory 420, the cache 430, and/or an additional memory/cache. Accordingly, in some embodiments, the processor 410 is connected to the memory 420, the cache 430, and/or the additional memory/cache. Executing the instructions may cause the processor 410 to perform one or more operations (e.g., operations used in training a machine learning model, operations used in inference using a trained machine learning model, etc.).

The memory 420 can include volatile memory and/or non-volatile memory. In some embodiments, the memory 420 includes tightly coupled memory (TCM) which may be a nearest or fastest memory accessible to the processing circuit 320. In some embodiments, the memory 420 may be SRAM. The memory 420 may be private to the processing circuit 320 (e.g., not accessible to the processing circuit 320) or the memory 420 may be accessible to a processor outside of the processing circuit 320 such as a processor included in an additional processing circuit 320 on the base die 150, as alluded to above.

It should be appreciated that, in some embodiments, the memory 420 can be partitioned such that a first portion of the memory 420 is private to the processing circuit 320 and a second portion of the memory 420 is accessible to other processing circuits 320. For instance, the first portion of the memory 420 that is private to the processing circuit 320 may not be used by the processing circuit 320 (e.g., the processing circuit 320 may not read from or write to the first portion of the memory 420). In some embodiments, the second portion of the memory 420 that is accessible to the other processing circuits 320 may be used by the other processing circuits 320 (e.g., the other processing circuits 320 can read from and write to the second portion of the memory 420).

In some embodiments, the engines 440, 450, 460 include compute engines (e.g., co-processors, logic blocks, arithmetic units, etc.) which may be configured to execute particular instructions or perform specialized operations. For example, the engines 440, 450, 460 may include cryptographic engines, compression engines, video processing engines, database processing engines, graphics engines, gaming engines, domain specific engines, etc. In some embodiments, the engine 440 includes a general matrix multiply engine and the engine 450 includes a math engine. The general matrix multiply engine can be configured for matrix-to-matrix multiplication acceleration and the math engine may be configured to process element-wise operations on floating point numbers (e.g., including basic math, exponentiation, and trigonometric functions).

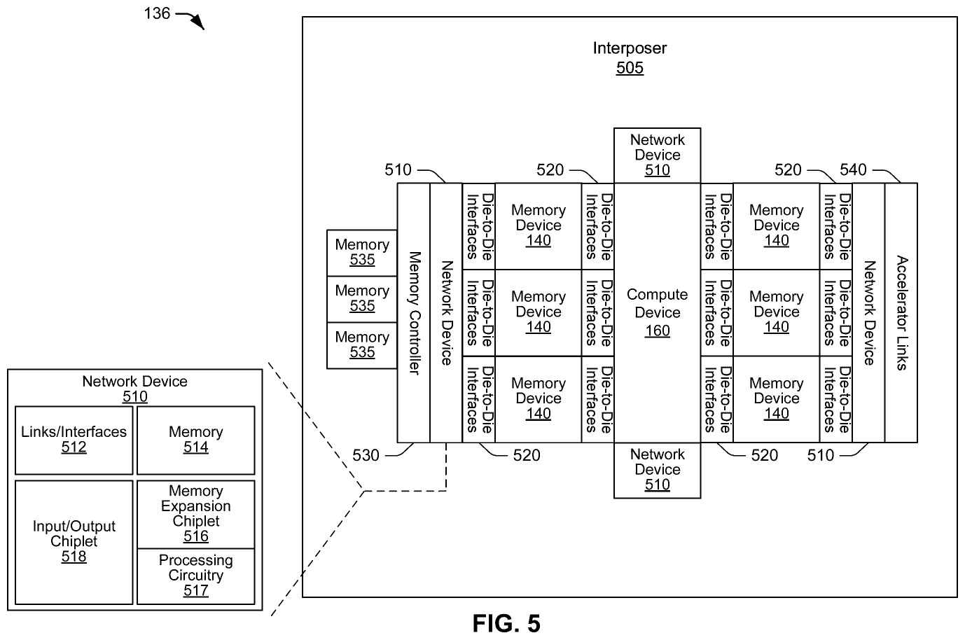

FIG. 5 illustrates an example of a system-in-package 136, according to embodiments of the disclosure. As depicted in FIG. 5, a system-in-package 136 may include one or more interposers 505, one or more memory devices 140, one or more compute devices 160, one or more network devices 510, one or more die-to-die interfaces 520, one or more memory controllers 530, one or more memories 535, and one or more accelerator links 540. The interposers 505 (e.g., silicon interposers) may be configured to communicatively couple some portions of the system-in-package 136 to other portions of the system-in-package 136.

In some embodiments, one or more interposers 505 may be configured to connect the system-in-package 136 with another system-in-package 136 or multiple other system-in-packages 136. Accordingly, the interposers 505 can comprise multiple smaller interposers 505 and the interposers 505 may be combined into larger interposers 505 (e.g., having a larger effective/functional area). For instance, one or more interposers 505 may represent or include bridges (e.g., silicon bridges), substrates, connection circuitry, package substrates, etc. In some embodiments, one or more interposers 505 may have or include relatively large dimensions such that each side of an interposer 505 may have a length greater than 50 millimeters, 60 millimeters, 70 millimeters, etc. It should be appreciated that, in some embodiments, one or more interposers 505 having the relatively large dimensions may improve thermal dissipation for the system-in-package 136 relative to an interposer having smaller dimensions than the relatively large dimensions.

In the example shown in FIG. 5, the memory devices 140 are connected to the network devices 510 by die-to-die interfaces 520. Also, the memory devices 140 are illustrated to be connected to the compute device 160 by die-to-die interfaces 520. In some embodiments, die-to-die interfaces 520 include one or more connections. For example, die-to-die interfaces 520 may include pairs of connected die-to-die interfaces 310 which may be connected by an interposer 505 in some embodiments (e.g., the interposer 505 may include a bridge that connects the die-to-die interfaces 310). For instance, die-to-die interfaces 520 may include a first die-to-die interface 310 of a memory device 140 and a second die-to-die interface 310 of a network device 510 or a second die-to-die interface 310 of the compute device 160. In some embodiments, die-to-die interfaces 520 can include various types of connections which are not limited to pairs of connected die-to-die interfaces 310.

In general, the compute device 160 is configured to manage/control operations of the system-in-package 136. In FIG. 5, the compute device 160 is illustrated to be connected to network devices 510. In some embodiments, the compute device 160 may be connected to the network devices 510 by interfaces such as die-to-die interfaces 310 integrated into the compute device 160. In other embodiments, the compute device 160 can be connected to the network devices 510 using various other interfaces/connections such as die-to-die interfaces 520.

As described above, in some embodiments, the compute device 160 includes the functionality of the optional second controller 340 which the compute device 160 uses to control processing circuits 320 included in the memory devices 140. In some embodiments, the compute device 160 can include a network on chip 315 that may be configured to support address mapping and a global memory map as described below. In these embodiments, a memory device 140 may be configured as a request initiator to enable data sharing between the memory devices 140. In some embodiments, the compute device 160 may not support data sharing between the memory devices 140 such that a processing circuit 320 of a first memory device 140 does not request access to a memory of a second memory device 140.

As illustrated in FIG. 5, a network device 510 may include links/interfaces 512, one or more memories 514, one or more memory expansion chiplets 516, and one or more input/output chiplets 518. In some embodiments, the network device 510 may be configured to communicatively couple various devices/components in a network-based architecture (e.g., using the links/interfaces 512). In some embodiments, the network device 510 may be structured similarly to (or the same as) the network on chip 315 described above.

In some embodiments, the network device 510 may include a network on chip 315 which may or may not be internal to the network device 510. In an example in which a network device 510 includes a network on chip 315, the network device 510 may be configured to facilitate data sharing between memory devices 140 connected to the network device 510 regardless of whether the compute device 160 supports such data sharing between the memory devices 140. It should be appreciated that the network on chip 315 may be internal to a base die 150 while the network device 510 may be external to the base die 150 such that the network device 510 can be coupled to the base die 150 via the die-to-die interfaces 520.

In some embodiments, network on chips 315 and network devices 510 may be configured to connect to or define different levels of networks. For example, a network on chip 315 may be configured to communicatively couple devices/components within a network at first level (e.g., a die level) and a network device 510 may be configured to communicatively couple devices/components within the network at second level (e.g., a card or package level). In some embodiments, the first level may include first types of devices and/or device connections and the second level can include second types of devices and/or device connections.

The memories 514 can include volatile and/or non-volatile memory. In some embodiments, the memories 514 include SRAM. It is to be appreciated that the memories 514 can be configured and/or used differently for different applications. The memories 514 may be used, for example, in address mapping which is described below.

In some embodiments, the memory expansion chiplets 516 are be configured to interface with one or more memory modules such as the memory controllers 530. In the illustrated example, a network device 510 is connected to a memory controller 530 that is communicatively coupled to one or more memories 535. In some embodiments, the memory controller 530 can be included on a memory expansion chiplet 516 such that the network device 510 can connect to and utilize the memories 535. In some embodiments, the memory expansion chiplet 516 is programmable and includes processing circuitry 517 (e.g., programmable processing circuitry) to facilitate particular movements of data between the memories 535. In some embodiments, the network device 510 may include direct memory access (DMA) engines which can access the memories 535 and/or additional memories 535.

The memories 535 can include volatile memory and/or non-volatile memory. In some embodiments, the memory controller 530 may include a low-power double data rate (LPDDR) memory controller and the one or more memories 535 may include LPDDR memory, e.g., to expand memory resources of the memory die 155 of the memory devices 140. For instance, the memories 535 can provide additional memory resources to supplement memory resources of the memory 202 of the memory die 155 used by the base die 150.

Address mapping (e.g., between the memory 202 and the memories 535) for memory expansion may be facilitated in any manner. In some embodiments, the memories 535 and other memories in a system-in-package 136 may be included in a global memory map such that the die-to-die interfaces 310 can be configured to direct/route data to and from the memories 535 and the other memories in the system-in-package 136. For example, one or more input/output chiplets 518 may be configured to direct/route data to and from the memories 535.

In some embodiments, the memory 202 and the memories 535 may form faster and slower tiers, respectively, of a tiered memory system. In specific applications, the memories 535 may be used for prefetching relatively large amounts of data such as a portion of a machine learning model. In a machine learning example, layer-by-layer data swapping from the memories 535 to the memory 202 may be performed to minimize latency (e.g., during a model inference).

As shown in FIG. 5, a network device 510 is connected to one or more accelerator links 540. In some embodiments, the input/output chiplets 518 are configured to interface with the accelerator links 540 which can include physical or logical connections. In some embodiments, the accelerator links 540 may be configured to connect to or function as an ultra accelerator link (UAlink) switch.

In some embodiments, one or more devices/components included in the system-in-package 136 are connected as part of a network that includes the network devices 510. For instance, the network device 510 illustrated in FIG. 5 to be connected to the accelerator links 540 may also be connected to the compute device 160, the memory controller 530, and the memories 535. Similarly, the network device 510 shown in FIG. 5 to be connected to the memory controller 530 may also be connected to the memories 535, the compute device 160, and the accelerator links 540. In some embodiments, the network that connects the one or more devices/components included in the system-in-package 136 may be at least partially included in one or more interposers 505 or the network can be separate from the one or more interposers 505. It should be appreciated that, in some embodiments, each device/component included in the system-in-package 136 may be connected to every other device/component included in the system-in-package 136, for example, as part of the network.

In some embodiments, the system-in-package 136 is communicatively coupled to one or more additional system-in-packages 136 by the accelerator links 540 as described below. In some embodiments, the network device 510 and/or the input/output chiplets 518 may be configured to support multiple interface protocols such as peripheral component interconnect express (PCIe), compute express link (CXL), non-volatile memory express (NVMe), and/or UALink. It should be appreciated that, in some embodiments, the input/output chiplets 518 include processors (e.g., management processors), DMA engines, memories (e.g., SRAM), etc.

Although FIG. 5 depicts six memory devices 140 that each include two die-to-die interfaces 310, it should be appreciated that the system-in-package 136 may include any number of memory devices 140 which can each include any number of die-to-die interfaces 310. Additionally, while FIG. 5 illustrates three memory devices 140 in each of two rows, in some embodiments, the system-in-package 136 includes memory devices 140 in other array-like arrangements. For example, the other array-like arrangements may include four memory devices 140, eight memory devices 140, 16 memory devices 140, etc. Additionally, while the memory devices 140 are illustrated in FIG. 5 to be the same or similar (e.g., a homogeneous system), in some embodiments, a first one of the memory devices 140 can be different from a second one of the memory devices 140. For example, the first and second ones of the memory devices 140 can have different processing capabilities, different memory capabilities, heterogeneous systems, etc.

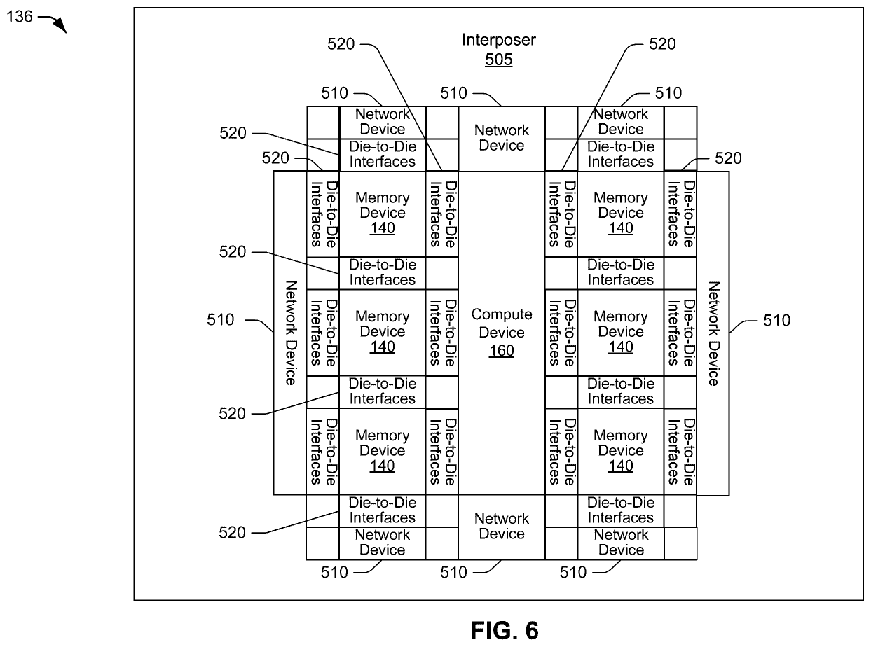

FIG. 6 illustrates an example of a system-in-package 136, according to embodiments of the disclosure. As shown in FIG. 6, a system-in-package 136 may include one or more interposers 505, one or more memory devices 140, one or more compute devices 160, one or more network devices 510, and one or more die-to-die interfaces 520. The system-in-package 136 illustrated in FIG. 6 is similar to the system-in-package 136 shown in FIG. 5. Unlike the system-in-package 136 shown in FIG. 5 in which the memory devices 140 have die-to-die interfaces 310 on two sides, in FIG. 6, the memory devices 140 include die-to-die interfaces 310 on four sides. As shown in FIG. 6, the memory devices 140 are connected to the network devices 510 by die-to-die interfaces 520. A compute device 160 is illustrated to be connected to the network devices 510 which may be the same devices connected to the memory devices 140 or different devices.

In some embodiments, the memory devices 140 may be directly connected to the network devices 510 (e.g., without die-to-die interfaces 520). It is to be appreciated that, in some embodiments, the memory devices 140 can be directly connected to one or more memory controllers 530 and/or accelerator links 540. For instance, the network devices 510 can include one or more input/output chiplets 518 and/or memory expansion chiplets 516 as described above.

In some embodiments, a memory device 140 connected to a network device 510 may be configured to function as an independent (e.g. partitioned) virtual accelerator unit. It is to be appreciated that, in some embodiments, the virtual accelerator unit may have a separate or a shared memory space. It is also to be appreciated that, in some embodiments, the system-in-package 136 can include multiple virtual accelerator units (e.g., multiple instances of a memory device 140 connected to a network device 510).

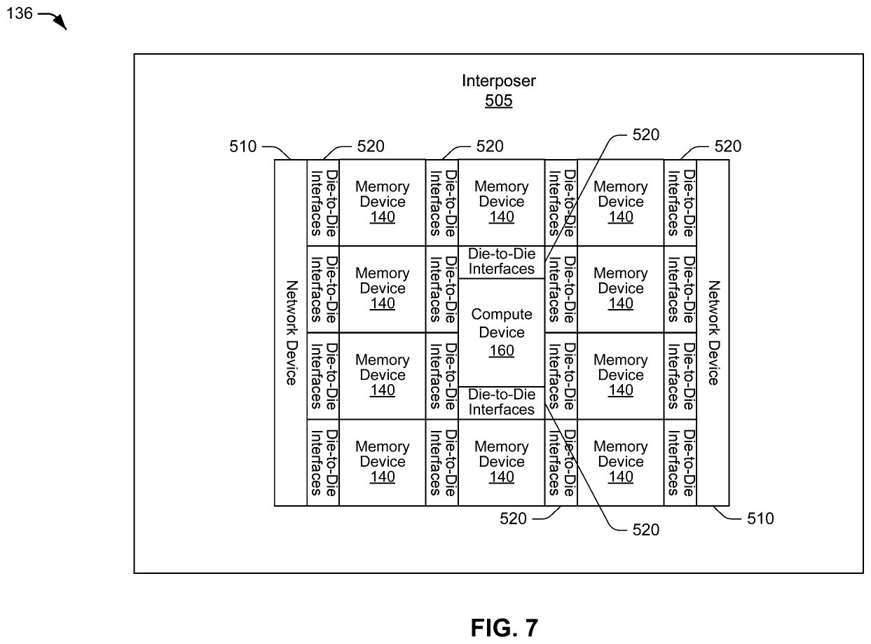

FIG. 7 illustrates an example of a system-in-package 136, according to embodiments of the disclosure. As shown, a system-in-package 136 may include one or more interposers 505, one or more memory devices 140, one or more compute devices 160, one or more network devices 510, and one or more die-to-die interfaces 520. The system-in-package 136 illustrated in FIG. 7 is similar to the system-in-package 136 shown in FIG. 5. Unlike the system-in-package 136 shown in FIG. 5 in which the compute device 160 is connected to the memory devices 140 on two sides, in FIG. 7, the compute device 160 is connected to the memory devices 140 on four sides. As shown in FIG. 7, the memory devices 140 are connected to the network devices 510 by die-to-die interfaces 520. As illustrated in FIG. 7, the memory devices 140 form a perimeter around the compute device 160. Some of the memory devices 140 forming the perimeter around the compute device 160 include die-to-die interfaces 310 which may be connected to other die-to-die interfaces 310 as described above.

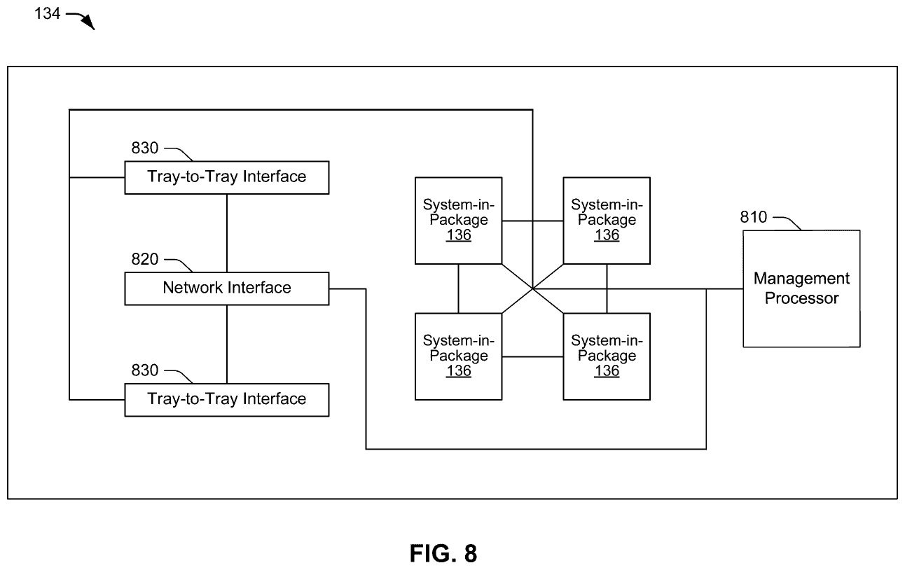

FIG. 8 illustrates a compute/memory tray 134, according to embodiments of the disclosure. As shown in FIG. 8, a compute/memory tray 134 may include one or more system-in-packages 136, a management processor 810, a network interface 820, and one or more tray-to-tray interfaces 830. Returning to the example shown in FIG. 1, the compute/memory tray 134 may be utilized as a group of compute and/or memory resources for performing operations by leveraging memory devices 140 (e.g., groups of the memory devices 140) included in the system-in-packages 136. It should be appreciated that, in some embodiments, the compute/memory tray 134 can be a standalone device or the compute/memory tray 134 may be communicatively coupled to an additional compute/memory tray 134. It should be further appreciated that the compute/memory tray 134 is not limited to a tray form factor. Instead, the compute/memory tray 134 may have or include any of a variety of different form factors such as drawers, racks, blocks, cards, blades, towers, etc.

As illustrated in FIG. 8, the system-in-packages 136 included in the compute/memory tray 134 are coupled together (e.g., by the accelerator links 540) such that each system-in-package 136 is connected to other system-in-packages 136 in the compute/memory tray 134. In some embodiments, the system-in-packages 136 may be connected in different ways that may or may not include the accelerator links 540. Further, while four system-in-packages 136 are illustrated in FIG. 8, the compute/memory tray 134 may include less than four system-in-packages 136 or more than four system-in-packages 136 in some embodiments.

As shown, the system-in-packages 136 are connected to the management processor 810 and the tray-to-tray interfaces 830. In some embodiments, the tray-to-tray interfaces 830 are connected to the system-in-packages 136 using UAlink connections, NVLink connections, etc. In some embodiments, the management processor 810 is connected to the system-in-packages 136 using PCIe connections, CXL connections, etc.

In general, the management processor 810 is configured to manage compute and/or memory resources included in the compute/memory tray 134. In some embodiments, the management processor 810 may be configured to control the system-in-packages 136 by controlling operations performed by one or more of the system-in-packages 136. In some embodiments, the management processor 810 can control operations performed by system-in-packages 136 by dividing (and optimizing the dividing) of a workload amongst the system-in packages 136, setting parameters therefore, collecting results thereof, transmitting commands, etc. It is to be appreciated that, in some embodiments, the management processor 810 may be configured to control the system-in-packages 136 based on inputs received from the machine 105 via the network 145 as described below.

The network interface 820 is also connected to the management processor 810 and the tray-to-tray interfaces 830. For instance, the network interface 820 may be configured to interface with the network 145 shown in FIG. 1. The tray-to-tray interfaces 830 may support ultra ethernet technology for connecting the compute/memory tray 134 to one or more additional compute/memory trays 134. It should be appreciated that, in some embodiments, the tray-to-tray interfaces 830 and/or the compute/memory tray 134 may support remote direct memory access (RDMA) over converged ethernet (RoCE), InfiniBand, etc. Accordingly, although the server 132 depicted in FIG. 1 includes one compute/memory tray 134, it is to be appreciated that, in some embodiments, the server 132 includes many compute/memory trays 134 (e.g., connected via the tray-to-tray interfaces 830).

With reference to FIG. 1, in an example in which the server 132 includes multiple compute/memory trays 134, the server 132 may utilize all of the compute/memory trays 134 or a portion of the compute/memory trays 134. For instance, the server 132 may utilize one of the compute/memory trays 134 for compute and/or memory resource needs below a resource threshold and the server 132 may utilize all of the compute/memory trays 134 for compute and/or memory resource needs at or above the resource threshold. In a machine learning example with respect to the server 132, the compute/memory tray 134 may be configured as a deployable platform for a large language model (LLM) with compute and/or memory resources capable of performing inference using the LLM with or without additional compute and/or memory resources of an additional compute/memory tray 134.

Consider a machine learning example in which the server 132 supports the LLM and a user input (e.g., a user query) for the LLM is received by the server 132 from the machine 105 via the network 145. In this example, the user input is a natural language question (e.g., a search query) and the LLM generates an output based on the user input in a summarization phase and a generation phase. In the summarization phase, the LLM represents the user input as one or more tokens. In the generation phase, the LLM processes the one or more tokens to generate the output.

In general, the summarization phase is “compute bound” (e.g., latency in the summarization phase is caused more by compute resource needs than by memory resource needs) while the generation phase is “memory bound” (e.g., latency in the generation phase is caused more by memory resource needs than by compute resource needs). Continuing the example, by including the compute/memory trays 134 in the server 132, the server 132 may reduce latency in both the summarization phase and the generation phase. For instance, in the summarization phase, the processing circuits 320 included in the memory devices 140 and the compute devices 160 included in the system-in-packages 136 may have sufficient compute resources to reduce latency. In the generation phase, the memory 202 of the memory die 155 included in the memory devices 140 can have sufficient memory resources to reduce latency. In some embodiments, if the compute and/or memory resources included in a first compute/memory tray 134 are not sufficient for either the summarization phase or the generation phase, then the server 132 may utilize the compute and/or memory resources of a second compute/memory tray 134.

Consider the example above in which performance of summarization/generation phases for the LLM can be improved by leveraging the compute devices 160 and the processing circuits 320 in different sequences. For example, after completion of a first summarization phase using the compute devices 160, the processing circuits 320 execute a generation phase corresponding to the first summarization phase. In this example, the compute devices 160 can then execute a second summarization phase (e.g., as the processing circuits 320 execute the generation phase). By implementing the compute devices 160 to execute the summarization phase (e.g., the “compute bound” phase based on processing involved in representing user inputs as one or more tokens) and implementing the processing circuits 320 to execute the generation phase (e.g., the “memory bound” phase based on data used in decoding representations of user inputs), the compute/memory tray 134 may include sufficient compute/memory resources for performing various machine learning operations using the LLM.

In some embodiments, efficiency of power consumption by the compute/memory tray 134 may be improved by dynamically determining which operations to perform with the compute devices 160 and which operations to perform with the processing circuits 320. For instance, a particular operation may be performed by the compute devices 160 or by the processing circuits 320. Depending on resource requirements for the particular operation, the processing circuits 320 may be more or less efficient at performing the particular operation than the compute devices 160. It is to be appreciated that, in some embodiments, dynamically determining which operations to perform with the compute devices 160 and which operations to perform with the processing circuits 320 may be based on one or more objectives such as minimizing consumption of a particular resource.

The following discussion is intended to provide a brief, general description of a suitable machine or machines in which certain aspects of the disclosure may be implemented. The machine or machines may be controlled, at least in part, by input from conventional input devices, such as keyboards, mice, etc., as well as by directives received from another machine, interaction with a virtual reality (VR) environment, biometric feedback, or other input signal. As used herein, the term “machine” is intended to broadly encompass a single machine, a virtual machine, or a system of communicatively coupled machines, virtual machines, or devices operating together. Exemplary machines include computing devices such as personal computers, workstations, servers, portable computers, handheld devices, telephones, tablets, etc., as well as transportation devices, such as private or public transportation, e.g., automobiles, trains, cabs, etc.

The machine or machines may include embedded controllers, such as programmable or non-programmable logic devices or arrays, application specific integrated circuits (ASICs), embedded computers, smart cards, and the like. The machine or machines may utilize one or more connections to one or more remote machines, such as through a network interface, modem, or other communicative coupling. Machines may be interconnected by way of a physical and/or logical network, such as an intranet, the Internet, local area networks, wide area networks, etc. One skilled in the art will appreciate that network communication may utilize various wired and/or wireless short range or long range carriers and protocols, including radio frequency (RF), satellite, microwave, Institute of Electrical and Electronics Engineers (IEEE) 802.11, Bluetooth®, optical, infrared, cable, laser, etc.

Embodiments of the present disclosure may be described by reference to or in conjunction with associated data including functions, procedures, data structures, application programs, etc. which when accessed by a machine results in the machine performing tasks or defining abstract data types or low-level hardware contexts. Associated data may be stored in, for example, the volatile and/or non-volatile memory, e.g., random access memory (RAM), read only memory (ROM), etc., or in other storage devices and their associated storage media, including hard-drives, floppy-disks, optical storage, tapes, flash memory, memory sticks, digital video disks, biological storage, etc. Associated data may be delivered over transmission environments, including the physical and/or logical network, in the form of packets, serial data, parallel data, propagated signals, etc., and may be used in a compressed or encrypted format. Associated data may be used in a distributed environment, and stored locally and/or remotely for machine access.

Embodiments of the disclosure may include a tangible, non-transitory machine-readable medium comprising instructions executable by one or more processors, the instructions comprising instructions to perform the elements of the disclosures as described herein.

The various operations of methods described above may be performed by any suitable means capable of performing the operations, such as various hardware and/or software component(s), circuits, and/or module(s). The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or steps of a method or algorithm and functions described in connection with the embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in random access memory (RAM), flash memory, read only memory (ROM), electrically programmable ROM (EPROM), electrically erasable programmable ROM (EEPROM), registers, hard disk, a removable disk, or any other form of storage medium known in the art.

Having described and illustrated the principles of the disclosure with reference to illustrated embodiments, it will be recognized that the illustrated embodiments may be modified in arrangement and detail without departing from such principles, and may be combined in any desired manner. And, although the foregoing discussion has focused on particular embodiments, other configurations are contemplated. In particular, even though expressions such as “according to an embodiment of the disclosure” or the like are used herein, these phrases are meant to generally reference embodiment possibilities, and are not intended to limit the disclosure to particular embodiment configurations. As used herein, these terms may reference the same or different embodiments that are combinable into other embodiments.

The foregoing illustrative embodiments are not to be construed as limiting the disclosure thereof. Although a few embodiments have been described, those skilled in the art will readily appreciate that many modifications are possible to those embodiments without materially departing from the novel teachings and advantages of the present disclosure. Accordingly, all such modifications are intended to be included within the scope of this disclosure as defined in the claims.

Consequently, in view of the wide variety of permutations to the embodiments described herein, this detailed description and accompanying material is intended to be illustrative only, and should not be taken as limiting the scope of the disclosure. What is claimed as the disclosure, therefore, is all such modifications as may come within the scope and spirit of the following claims and equivalents thereto.

What is claimed is:

1. An apparatus comprising:
a first memory device comprising:
a first base die comprising a first die-to-die interface, a second die-to-die interface, and a first processing circuit; and
a first memory die attached to the first base die;
a second memory device comprising:
a second base die comprising a third die-to-die interface, a fourth die-to-die interface, and a second processing circuit; and
a second memory die attached to the second base die; and
a compute device connected to the first die-to-die interface and the third die-to-die interface.

2. The apparatus according to claim 1, further comprising a network device connected to the second die-to-die interface.

3. The apparatus according to claim 2, wherein the network device is configured to interface with an accelerator link.

4. The apparatus according to claim 2, wherein the network device is configured to interface with a memory controller.

5. The apparatus according to claim 4, wherein the memory controller comprises a low power double data rate (LPDDR) memory controller.

6. The apparatus according to claim 2, wherein the network device is connected to the compute device.

7. The apparatus according to claim 2, wherein the network device is connected to the fourth die-to-die interface.

8. An apparatus comprising:
a first system-in-package comprising:
a first memory device comprising:
a first base die comprising a first processing circuit and a first die-to-die interface; and
a first memory die attached to the first base die; and
a first compute device connected to the first die-to-die interface;
a second system-in-package comprising:
a second memory device comprising:
a second base die comprising a second processing circuit and a second die-to-die interface; and
a second memory die attached to the second die-to-die interface; and
a second compute device connected to the second die-to-die interface; and
a first processor connected to the first system-in-package and the second system-in-package.

9. The apparatus according to claim 8, wherein the first system-in-package is connected to the second system-in-package by an accelerator link.

10. The apparatus according to claim 8, further comprising a first interface configured to connect the first system-in-package to a third system-in-package that is connected to a second processor.

11. The apparatus according to claim 10, further comprising a second interface configured to connect the first processor to a network.

12. The apparatus according to claim 11, wherein the first interface is connected to the second interface.

13. The system according to claim 8, wherein the first base die comprises a third die-to-die interface connected to a network device.

14. The system according to claim 13, wherein the network device is configured to interface with a low power double data rate (LPDDR) memory controller.

15. A system comprising:
a first tray comprising:
a first system-in-package comprising:
a first memory device comprising:
a first base die comprising a first processing circuit; and
a first memory die attached to the first base die; and
a first compute device connected to the first memory device; and
a second system-in-package comprising:
a second memory device comprising:
a second base die comprising a second processing circuit; and
a second memory die attached to the second base die; and
a second compute device connected to the second memory device; and
a first interface; and
a second tray comprising:
a third system-in-package comprising:
a third memory device comprising:
a third base die comprising a third processing circuit; and
a third memory die attached to the third base die; and
a third compute device connected to the third memory device; and
a second interface connected to the first interface.

16. The system according to claim 15, wherein the first system-in-package is connected to the first interface and the third system-in-package is connected to the second interface.

17. The system according to claim 15, wherein the first tray comprises a processor connected to the first system-in-package and the second system-in-package.

18. The system according to claim 15, wherein the first tray comprises a third interface configured to connect the processor to a network.

19. The system according to claim 18, wherein the first interface is connected to the third interface.

20. The system according to claim 15, wherein the first system-in-package is connected to the second system-in-package by an accelerator link.
